(19) United States
(12) Patent Application Publication
(10) Pub. No.: US 2026/0188395 A1
(43) Pub. Date: Jul. 2, 2026

(54) RETAINING DATA DURING LOW-POWER EVENTS

(71) Applicant: Micron Technology, Inc., Boise, ID (US)

(72) Inventors: Liang Yu, Boise, ID (US); Jonathan S. Parry, Boise, ID (US)

(21) Appl. No.: 19/429,944

(22) Filed: Dec. 22, 2025

Related U.S. Application Data
(60) Provisional application No. 63/739,052, filed on Dec. 26, 2024.

(51) Int. Cl. G11C 16/30; G11C 5/14; G11C 16/34

(52) U.S. Cl. CPC G11C 16/30; G11C 5/147; G11C 16/3404

(57) ABSTRACT

A memory system may receive an indication that a low-power mode associated with the memory system has been activated, and a voltage supplied to the memory system may be altered as a result of the low-power mode being activated. In accordance with receiving the indication, the memory system may perform one or more operations to extend a duration after the voltage is altered during which a voltage applied to the volatile memory device remains above a threshold voltage associated with retaining data stored in the volatile memory device.

### CROSS REFERENCE

The present application for patent claims priority to U.S. Patent Application No. 63/739,052 by Yu et al., entitled “RETAINING DATA DURING LOW-POWER EVENTS,” filed Dec. 26, 2024, which is assigned to the assignee hereof, and which is expressly incorporated by reference in its entirety herein.

### TECHNICAL FIELD

The following relates to one or more systems for memory, including retaining data during low-power events.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports retaining data during low-power events in accordance with examples as disclosed herein.

FIG. 2 shows an example of a subsystem that supports retaining data during low-power events in accordance with examples as disclosed herein.

FIGS. 3A through 3C show examples of a voltage regulation component that supports retaining data during low-power events in accordance with examples as disclosed herein.

FIG. 4A shows an example of a set of operations for retaining data during low-power events in accordance with examples as disclosed herein.

FIGS. 4B and 4C show examples of graphs for retaining data during low-power events in accordance with examples as disclosed herein.

FIG. 5A shows an example of a set of operations for retaining data during low-power events in accordance with examples as disclosed herein.

FIGS. 5B and 5C show examples of graphs for retaining data during low-power events in accordance with examples as disclosed herein.

FIG. 6A shows an example of a set of operations for retaining data during low-power events in accordance with examples as disclosed herein.

FIGS. 6B and 6C show examples of graphs for retaining data during low-power events in accordance with examples as disclosed herein.

FIG. 7 shows a block diagram of a memory system that supports retaining data during low-power events in accordance with examples as disclosed herein.

FIG. 8 shows a flowchart illustrating a method or methods that support retaining data during low-power events in accordance with examples as disclosed herein.

### DETAILED DESCRIPTION

When a device enters a low-power state, the power supplied to a memory system may be reduced or removed. As a result of the power supplied to the memory system being reduced or removed, a voltage of a conductor (which may be referred to as a “supply rail”) used to supply power to components within the memory system may also be reduced as the conductor is discharged by the components of the memory system. In some examples, the duration associated with the supply rail of the memory system being discharged below the data retention voltage is likely to be less than the duration associated with the host system removing and returning power. Accordingly, there is a high probability of the memory system performing the initialization procedure and reconfiguring the memory system settings each time the host system enters low-power modes associated with extended sleep durations (e.g., UFS SSU sleep or hibernate). But performing the initialization procedure and reconfiguring the memory system settings may cause excessive latency to be associated with the host system accessing the memory system after returning to the active state. Thus, implementations (e.g., methods, systems, apparatuses, techniques, configurations, components) that enable a host system to access a memory system with lower latency after wake-up may be desired.

To enable a host system to access a memory system with lower latency after wake-up, techniques may be used that enable the memory system to maintain core configurations (e.g., results of the initialization procedure and settings) while the host system is in a low-power state and, thus, avoid executing the startup procedure. For example, techniques may be implemented that extend a duration during which a voltage on a conductive path between a host system and memory system remains above a threshold voltage associated with retaining data within volatile memory. In some examples, a length of the duration is based on a time for which a host system is likely to remain in a low-power state.

In addition to applicability in memory systems as described herein, techniques for retaining data during low-power events may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing a latency associated with exiting low-power states, which may decrease processing or latency times, improve response times, or otherwise improve user experience, among other benefits.

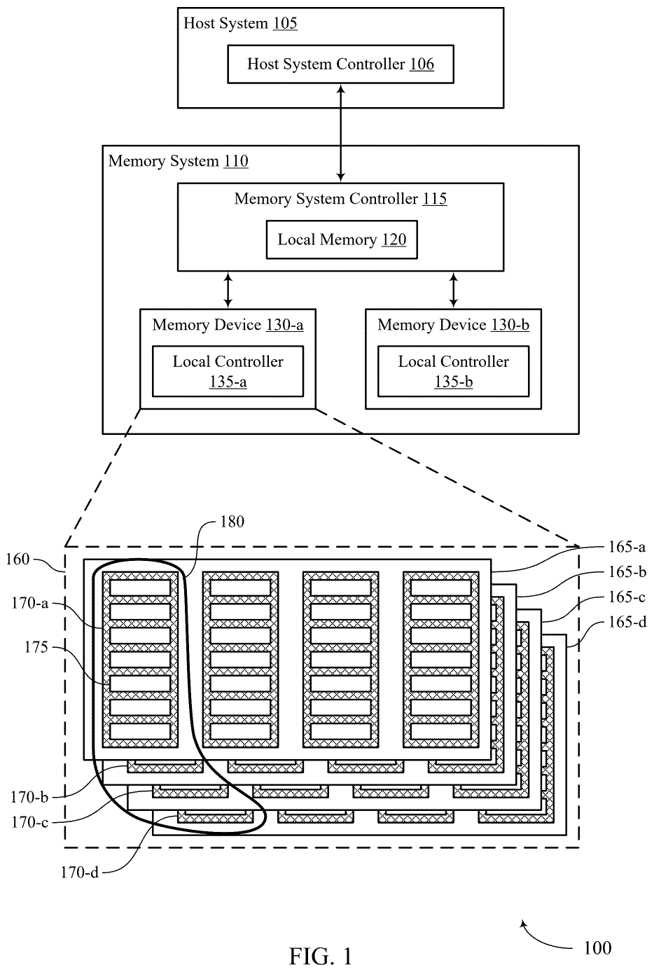

FIG. 1 shows an example of a system 100 that supports retaining data during low-power events in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

A memory system may be configured to perform a startup procedure (e.g., when the memory system is first turned on, after a recovery event, etc.), which may include executing one or more initialization procedures (e.g., calibration procedures, testing procedures, etc.) and configuring one or more settings (e.g., drive strengths, voltage levels, trims, etc.) for the memory system (e.g., for individual dies in the memory system). In some examples, the memory system may be inaccessible (e.g., by a host system) until the startup procedure has completed. The code for executing the startup procedure and configuring the one or more settings may be stored in nonvolatile, read-only memory (e.g., fuses) within the memory system. In such cases, on startup, the code may be loaded from the read-only memory and then executed. Also, the settings may be loaded from the read-only memory and distributed throughout the memory system (e.g., to latches and registers). In some examples, the results of the startup procedure and the settings may be stored in logic components (e.g., latches and registers) in the memory system.

A memory system may include volatile memory—e.g., for low-latency and/or high-bandwidth access operations, such as buffering and caching. For example, the memory system may include one or more volatile memory devices (e.g., SRAM device). In some examples, the results of the startup procedure and the settings may also be stored in an SRAM device at the memory system. In some examples, the host system may access the results of the startup procedures and settings from the SRAM device (e.g., rather than from latches and registers).

A memory system may be capable of operating in different modes. For example, a memory system may be capable of operating in a standby mode. While in the standby mode, the memory system may draw a lower current amount than in other modes, such as an active mode (e.g., the memory system may draw around a hundred μA per memory die). Additionally, or alternatively, the memory system may be capable of operating in a low-power standby mode. While in the low-power standby mode, the memory system may draw a lower current amount than in other modes, such as the standby mode (e.g., the memory system may draw tens of μA per memory die). In some examples, the SRAM devices may be operated at a desired voltage (e.g., 2.25 V) but may be capable of retaining data at voltages that are lower than the operating voltage (e.g., as low as 0.8 V).

A host system may be electrically coupled with a memory system by a conductive path (e.g., which may include one or more conductive traces, one or more conductive wires, etc.) and may be configured to energize (e.g., via a power management integrated circuit) a supply rail of the memory system. In some cases, the host system may provide the memory system with a constant voltage (e.g., 2.35 V). The memory system may power certain internal components using the received voltage and may power other internal components using different (e.g., higher or lower) voltages. For example, the memory system may power an ASIC for managing SRAM using the received voltage while powering memory devices (e.g., SRAM devices, NAND devices) using a lower voltage (e.g., 1.8 V).

To obtain the lower voltage, the memory system may include power electronic circuitry that converts the received voltage to the lower voltage. In some examples, the power electronic circuitry is a low-dropout voltage regulator. A low-dropout voltage regulator may generate a variable resistance between its input and output to ensure that a desired voltage (e.g., the lower voltage) is output to downstream circuitry. In some examples, when a difference between the input voltage and the output voltage is less than or equal to a threshold amount (which may be referred to as the dropout voltage)—e.g., when power is removed from the input of the low-dropout voltage regulator—the low-dropout voltage regulator may provide a default resistance between its input and the output. In the event of power loss, this default resistance may consume energy as the remaining energy stored in and along the conductive path between the host system and memory system is drawn from the conductive path.

A device (e.g., a mobile device) may utilize low-power (e.g., sleep) modes to conserve power. While in a low-power mode, the device may disable a portion (or all) components of the device. In some examples, the device may disable all components of the device except for a “listening component” that is configured to listen for a “wake up” signal and to trigger a wake up of the disabled components. In some examples, the device may also periodically disable the listening component in accordance with a listening schedule. Accordingly, a power consumption of the device may be reduced while the low-power mode is activated.

In certain low-power modes (e.g., UFS SSU sleep or hibernate), a host system in a device may disconnect power to a memory system in the device—e.g., by shutting of a power source used to power the memory system. Once power is removed from the memory system, the voltage of its supply rail may drop—e.g., as a result of intended and parasitic resistive paths to ground, current draw of active components of the memory system, etc. Particularly, the voltage of the supply rail may drop based on the charge that is capacitively stored along the communication path between the host system and the memory system (e.g., in capacitors in the host system, capacitors in the memory system, parasitic capacitances) and the current drawn from the supply rail. The duration for the voltage of the supply rail voltage to drop to zero may be represented as:

$$\frac{( {Cap}_{Ttl} \times {V}_{Supply} )}{Ttl current draw} .$$

When the voltage level of the supply rail drops below a “data retention” voltage threshold (e.g., 1.2V), initialization procedure results and the settings (e.g., LUN trims, set features, ONFI settings) stored for the memory system (e.g., in the SRAM, latches, and/or registers) may be lost (e.g., once the voltage level drops below a threshold level). The duration for the voltage of the supply rail voltage to drop to zero may be represented as:

$$\frac{( {Cap}_{Ttl} \times ( {V}_{Supply} - {V}_{Threshold} )}{Total current draw}$$

Accordingly, to ensure stable performance, the memory system may monitor the voltage level of the supply rail. In such cases, if the voltage level of the supply rail is less than or equal to the threshold level, the memory system may perform the initialization procedure and reconfigure the settings of the memory system when the device returns to an active state and power is returned to the memory system. In some cases, reconfiguring the settings of the memory system may include restoring various parameters to the SRAM, latches, and/or registers that were lost in response to the voltage dropping below a threshold.

In some examples, the duration associated with the supply rail of the memory system being discharged below the data retention voltage is likely to be less than the duration associated with the host system removing and returning power. Accordingly, there is a high probability of the memory system performing the initialization procedure and reconfiguring the memory system settings each time the host system enters low-power modes associated with extended sleep durations (e.g., UFS SSU sleep or hibernate). But performing the initialization procedure and reconfiguring the memory system settings may cause additional latency to be associated with the host system accessing the memory system after returning to the active state. Thus, implementations (e.g., methods, systems, apparatuses, techniques, configurations, components) that enable a host system to access a memory system with lower latency after wake-up may be desired.

To enable a host system to access a memory system with lower latency after wake-up (at least in some cases), techniques may be used that enable the memory system to maintain core configurations (e.g., results of the initialization procedure and settings) while the host system is in a low-power state and, thus, avoid executing the startup procedure. For example, techniques may be implemented that extend a duration during which a voltage on a conductive path (e.g., a supply rail) between a host system and memory system remains above a threshold voltage associated with retaining data within volatile memory (e.g., SRAM, a page buffer (e.g., a scatter page buffer (SPB)) of the memory system). In some examples, a length of the duration is based on a time for which a host system is likely to remain in a low-power state.

In some examples, the duration is extended by implementing power electronic circuitry that is configured to avoid accelerating the voltage drop on the conductive path when power is removed from the power electronic circuitry. Additionally, or alternatively, the duration may be extended by implementing a low-power mode (which may be referred to as a low-power data retention (LPDR) mode) that is specifically configured for retaining data in volatile memory components when power is lost at the memory system. The LPDR mode may be configured to reduce (e.g., by disabling all components except for components that support SRAM operation, by disabling portions of the SRAM not configured to store core configurations, etc.) the current draw of the memory system relative to other low-power modes, such as the low-power standby mode (e.g., the memory system may draw less than thirty (30) μA per memory die).

In some examples, the memory system 110 may receive a “low-power indication” that a low-power mode (e.g., an SSU sleep or hibernate mode) is activated at a device that includes a host system 105 and the memory system 110. Based on the low-power mode being activated, power to the memory system may be removed (e.g., shut off). Based on receiving the low-power indication, the memory system 110 may perform one or more operations for extending a duration (that begins after the power is removed from the memory system) during which a voltage applied to certain volatile memory components (e.g., an SRAM device, a scattered page buffer (SPB), etc.) of the memory system 110 remains above a “data retention voltage” threshold, where the certain volatile memory components may be associated with core configurations of the memory system 110.

The one or more operations may include causing the memory system 110 to enter a low-power data retention mode that significantly reduces the current draw of the memory system (e.g., by disabling all or most components no associated with retaining data in SRAM); implementing a voltage regulation system for the SRAM that increases a duration during which a voltage on a conductor that supplies the voltage regulation system remains above a threshold; directing the host system 105 to refrain from actively discharging a power management component that supplies power to the memory system 110, or any combination thereof.

By extending the duration during which a voltage applied to certain volatile memory devices remains above a data retention voltage threshold, these volatile memory devices may continue to operate i.e., the residual energy in the power system (e.g., in capacitance along a conductive path between the host system and the volatile memory device) may be used to continue to power these volatile memory devices.

The system 100 may include any quantity of non-transitory computer readable media that support retaining data during low-power events. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

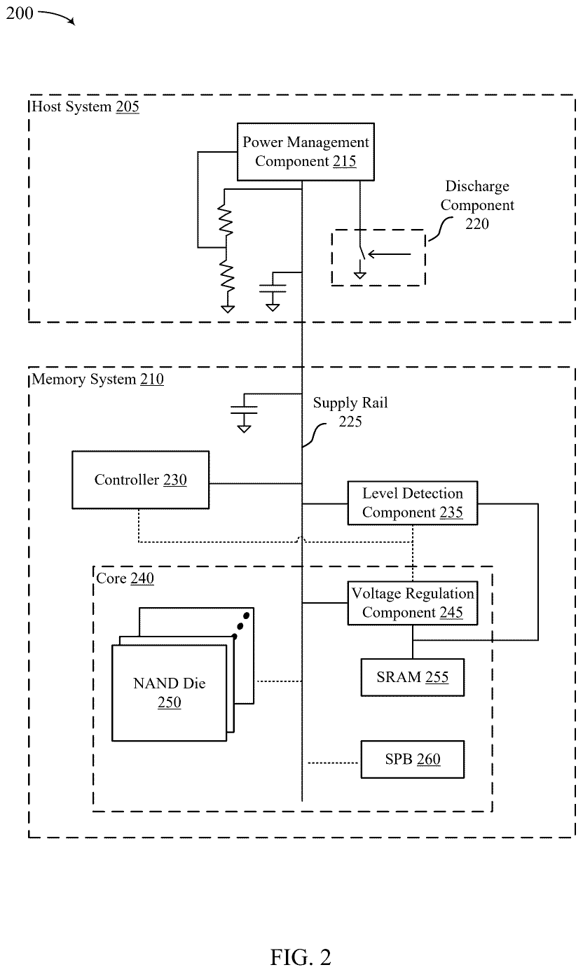

FIG. 2 shows an example of a subsystem that supports retaining data during low-power events in accordance with examples as disclosed herein.

The subsystem 200 may include the host system 205 and the memory system 210, which may be respective examples of the host system 105 and the memory system 110 of FIG. 1.

The host system 205 may include the power management component 215. The power management component 215 may be configured to supply power to other components, such as the memory system 210, at a constant voltage (e.g., 2.35V). In some examples, the power management component 215 is a power management integrated circuit (PMIC). The power management component 215 may include a feedback loop that uses a resistor voltage divider circuit to detect the output voltage of the power management component. The power management component 215 may also include a discharge component 220, which may be used to rapidly discharge the voltage supplied by the power management component 215 to a ground reference voltage. The power management component 215 may also be coupled with a capacitor (e.g., having a capacitance in the tens of microfarads), which may be used to smooth out the voltage output by the power management component 215 (e.g., by regulating variations in the voltage output by the power management component).

The components coupled with the power management component 215 may draw power during operation of the power management component 215. For example, the resistor voltage divider may draw hundreds of microwatts (2.35V*tens of microamperes) and the capacitor may draw less than one microwatt (2.35V*hundreds of nanoamperes). These components may similarly draw power from the conductive path between the power management component 215 and these components after the power management component 215 is deactivated—e.g., until the energy stored on the conductive path is depleted. The conductive path may include a conductive trace within the host system 205 that connects the power management component 215 to an output node (e.g., pin, ball, etc.) on the host system 205, a conductive trace or wire between the output node of the host system 205 and an input node of the memory system 210, and the supply rail 225 within the memory system 210.

The memory system 210 may include the controller 230, the level detection component 235, and the core 240. The memory system 210 may also be coupled with a capacitor (e.g., having a capacitance greater than 0.1 microfarads), which may be used to smooth out the voltage received at the memory system 210 from the power management component 215. In some examples, the memory system 210 may be configured to implement a low-power data retention mode that is used to significantly reduce the current drawn by the NAND dies (including the NAND die 250) when the memory system 210 detects that a device including the host system 205 has entered a low-power mode (e.g., SSU or hibernate mode). In some examples, the memory system 210 may be further configured to deactivate a portion of the SRAM 255 (e.g., a portion that does not store core configuration or settings) while in the low-power data retention mode to further reduce a current draw within the memory system 210.

The controller 230 may be used to control the SRAM 255 within the core 240. For example, the controller 230 may be used to read and write data to the SRAM 255, to store an initialization procedure to the SRAM 255, to execute the initialization procedure for the memory system 210 (e.g., using the code and data stored in the SRAM), and the like. In some examples, the controller 230 operates at around the voltage provided by the power management component 215 (e.g., around 2.35 V).

The level detection component 235 may be configured to detect one or more voltages in the memory system 210. In some examples, the level detection component 235 is used to detect the voltage of the supply rail 225, the voltage output by the voltage regulation component 245, and the like. The level detection component 235 may be composed of a single component or may be composed of multiple components that are distributed through the memory system 210. For examples, a component of the level detection component 235 may be included within the core 240.

The core 240 may include one or more (e.g., eight) NAND dies, such as the NAND die 250, the voltage regulation component 245, the SRAM 255, and the SPB 260. The SRAM 255 may be configured to store data associated with low-latency and/or high-bandwidth access operations, such as buffering and caching. In some examples, the results of a startup procedure and settings for the memory system 210 may be stored in the SRAM 255 (e.g., in a portion of the SRAM). The SRAM 255 may include one or more SRAM dies.

The SPB 260 may be configured to temporarily store data read from a NAND die—e.g., in response to a request from the host system for the data. The SPB 260 may also be configured to temporarily store data to be written to a NAND die—e.g., in response to a request from the host system to write the data.

The components of the memory system 210 may draw power during operation of the memory system 210. The components may similarly draw power from the conductive path between the power management component 215 and these components after the power management component 215 is deactivated—e.g., until the energy stored on the conductive path is depleted. For example, the controller 230 may draw around a hundred microwatts at a certain voltage (e.g., 2.35 V). Also, the NAND dies may each draw hundreds of microwatts at the certain voltage while in a standby mode. A lower amount of power (e.g., low hundreds of microwatts) at the certain voltage while in a low-power standby mode. And an even lower amount of power (e.g., tens of microwatts) at the certain voltage while in a low-power data retention mode. In some examples, the typical per-NAND die current draw in the low-power data retention mode may be between one (1) and thirty (30) microamperes.

As described herein, the time for depleting the energy stored on the conductive path may be based on the voltage of the conductive path, the capacitance coupled with the conductive path, and the total current being drawn from the conductive path after the power is removed from the conductive path. Similarly, the time for depleting an amount of energy associated with the conductive path having a threshold voltage may be based on the voltage of the conductive path, the capacitance, the current draw, and the threshold voltage (which may be based on a voltage at which the SRAM 255 is capable of retaining stored data). As an example, the “voltage-hold duration” for the voltage of the supply rail 225 to drop to the threshold voltage may be computed as

$$\frac{( 35 µ F \times ( 2.35 V - 1.2 V )}{500 µA} \approx 80.5 milliseconds .$$

In some examples, with such a configuration, the power management component 215 may restore power (e.g., when the host system 205 returns to an active state) to the supply rail 225 before the voltage of the supply rail 225 is less than or equal to the threshold voltage in many (e.g., over 90%) of cases). In some cases, the memory system 210 may be configured to further extend the voltage-hold duration by further reducing the power draw of the low-power data retention mode (e.g., by disabling a portion of the SRAM 255). In some cases, the SRAM 255 may be an example of any type of volatile memory device used by a memory system as a cache. Other examples may include latches, registers, and/or DRAM.

The voltage regulation component 245 may be configured to convert the voltage received from the supply rail to a second (e.g., lower voltage). The voltage regulation component 245 may be further configured to extend the duration during which the voltage of the supply rail 225 remains above the threshold voltage.

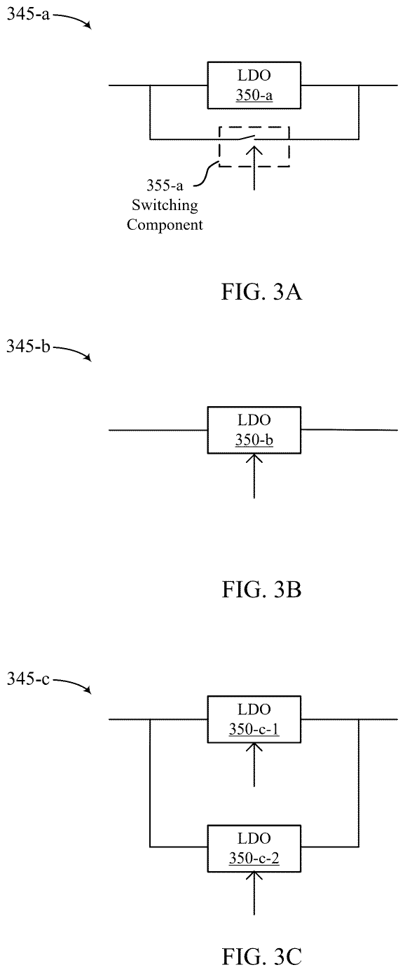

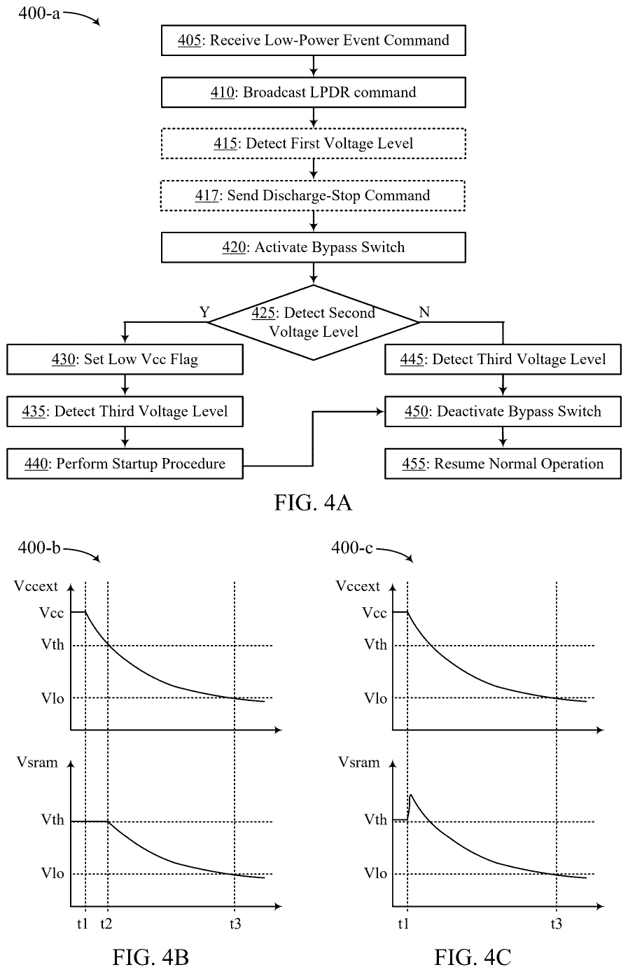

In some examples, the voltage regulation component 245 may include a low-dropout voltage regulator that is coupled with a bypass switch, as described herein including with reference to FIGS. 3A and 4A through 4C.

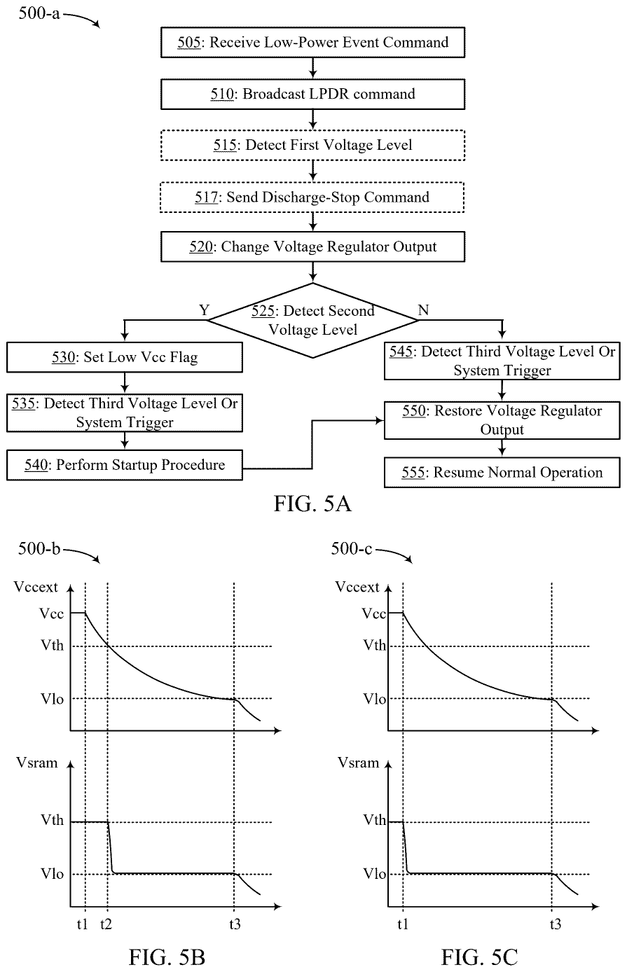

In some examples, the voltage regulation component 245 may include a low-dropout voltage regulator that is configurable between two output voltages (e.g., a normal operating output voltage, around 1.8 V, and a low operating output voltage, around 1.2V), as described herein including with reference to FIGS. 3B and 5A through 5C.

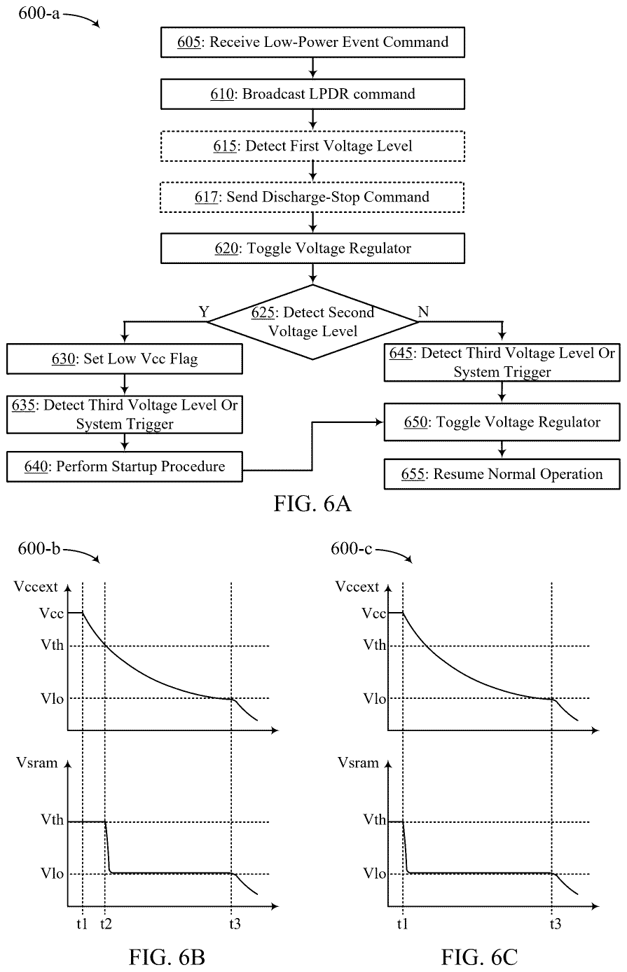

In some examples, the voltage regulation component 245 may include a first low-dropout voltage regulator that generates a first output voltage (e.g., a normal operating output voltage, around 1.8 V) and a second parallel low-dropout voltage regulator that generates a second output voltage (e.g., a low operating output voltage, around 1.2V), as described herein including with reference to FIGS. 3C and 6A through 6C.

The foregoing may extend the duration that the voltage of the supply rail 225 remains above the threshold voltage relative to voltage regulation component that includes a single low-dropout voltage regulator that cannot be bypassed or reconfigured as such a low-dropout voltage regulator would introduce a significant resistance into the deactivated supply system and would cause the energy to be dissipated from the supply rail 225 more quickly.

FIG. 3A shows an example of a voltage regulation component that supports retaining data during low-power events in accordance with examples as disclosed herein.

The voltage regulation component 345-a includes a low-dropout voltage regulator 350-a and a switching component 355-a. The low-dropout voltage regulator 350-a may be configured to receive a first supply voltage having a first voltage and generate a second supply voltage (for a downstream SRAM) having a second voltage. The switching component 355-a may be configured to bypass the low-dropout voltage regulator 350-a when the first supply voltage, the second supply voltage, or both, is less than or equal to a threshold voltage (e.g., after power is removed from a memory system including the voltage regulation component 345-a). In some examples, the switching component 355-a is controlled by (or based on) the output of a level detection component, such as the level detection component 235 of FIG. 2. In some examples, the switching component 355-a is controlled by (or based on) a system component, such as the controller 230 of FIG. 2, sending a trigger indicating that the memory system 210 is entering a low-power data retention mode.

Operation of the voltage regulation component 345-a in the context of a subsystem (e.g., the subsystem 200 of FIG. 2) is described in more detail herein, including with reference to FIGS. 4A through 4C.

FIG. 3B shows an example of a voltage regulation component that supports retaining data during low-power events in accordance with examples as disclosed herein.

The voltage regulation component 345-b includes a low-dropout voltage regulator 350-b that can be configured to output a first voltage (e.g., around 1.8V) and a second voltage (e.g., around 1.2V). The low-dropout voltage regulator 350-b may be configured to receive a first supply voltage having a first voltage (e.g., 2.35V) and generate a second supply voltage (for a downstream SRAM) having a second voltage (e.g., 1.8V). The low-dropout voltage regulator 350-b may be further configured to receive the first supply voltage having a first voltage (e.g., between 1.2V and 2.35V) and generate a second supply voltage (for a downstream SRAM) having a second voltage (e.g., 1.2V) when power is removed from a memory system including the voltage regulation component 345-b. In some examples, the output of the low-dropout voltage regulator 350-b is controlled by (or based on) the output of a level detection component, such as the level detection component 235 of FIG. 2. In some examples, the output of the low-dropout voltage regulator 350-b is controlled by (or based on) a system component, such as the controller 230 of FIG. 2, sending a trigger indicating that the memory system 210 is entering a low-power data retention mode.

Operation of the voltage regulation component 345-b in the context of a subsystem (e.g., the subsystem 200 of FIG. 2) is described in more detail herein, including with reference to FIGS. 5A through 5C.

FIG. 3C shows an example of a voltage regulation component that supports retaining data during low-power events in accordance with examples as disclosed herein.

The voltage regulation component 345-c includes a first low-dropout voltage regulator 350-c-1 that can be configured to output a first voltage (e.g., around 1.8V) and a second low-dropout voltage regulator 350-c-2 that can be configured to output a second voltage (e.g., around 1.2V). The first low-dropout voltage regulator 350-c-1 may be configured to receive a first supply voltage having a first voltage (e.g., 2.35V) and generate a second supply voltage (for a downstream SRAM) having a second voltage (e.g., 1.8V). The second low-dropout voltage regulator 350-c-2 may be further configured to receive the first supply voltage having a first voltage (e.g., between 1.2V and 2.35V) and generate a second supply voltage (for a downstream SRAM) having a second voltage (e.g., 1.2V) when power is removed from a memory system including the voltage regulation component 345-c. In some examples, which of the first low-dropout voltage regulator 350-c-1 and the second low-dropout voltage regulator 350-c-2 is controlled by (or based on) the output of a level detection component, such as the level detection component 235 of FIG. 2. In some examples, which of the first low-dropout voltage regulator 350-c-1 and the second low-dropout voltage regulator 350-c-2 is controlled by (or based on) a system component, such as the controller 230 of FIG. 2, sending a trigger indicating that the memory system 210 is entering a low-power data retention mode.

Operation of the voltage regulation component 345-c in the context of a subsystem (e.g., the subsystem 200 of FIG. 2) is described in more detail herein, including with reference to FIGS. 6A through 6C.

FIG. 4A shows an example of a set of operations for retaining data during low-power events in accordance with examples as disclosed herein.

The flowchart 400-a may be performed by a memory system, such as a memory system described herein. In some examples, the flowchart 400-a shows an example set of operations performed to support retaining data during low-power events. For example, the flowchart 400-a may include operations for activating a switch that bypasses a voltage regulator when power is removed from the memory system—e.g., to extend the duration during which the voltage of a conductive path coupled with the input of the voltage regulator remains above a threshold voltage.

At 405, a low-power event command (e.g., an SSU or hibernate command) may be received at a memory system. The low-power event command may indicate that a device (or host system in the device) is in a low-power state or is entering a low-power state (e.g., within a threshold duration). In some examples, the low-power event command indicates and/or is associated with power being removed from the memory system.

At 410, a low-power data retention command may be broadcast throughout the memory system—e.g., to all of the components within the memory system. The low-power data retention command may cause a majority of the components to be disabled or to power-gate internal circuitry. In some examples, the low-power data retention command may cause all components within the memory system, except for SRAM components (e.g., SRAM, SRAM control circuitry, etc.), to be disabled or power-gated. In some examples, the low-power data retention command further causes a portion of the SRAM to be disabled or power-gated (e.g., the portion of the SRAM that is not storing core configuration information for the memory system, such as testing results, calibration results, or settings), which may further reduce a current draw of the SRAM. In some examples, the low-power data retention command may cause all components within the memory system, except for SRAM components and voltage detection components used to support controlling voltage regulation for the SRAM component (e.g., all or a portion of an SRAM die), to be disabled or power-gated. In some examples, one or more buffer components (e.g., a scattered page buffer) may be maintained in an active state while the memory system is in the low-power data retention mode.

At 415, it may be detected (e.g., by a level detection component 235) that a voltage level of a supply rail within the memory system is less than or equal to a first threshold voltage (e.g., which may equivalent to Vth depicted in FIGS. 4B and 4C). Additionally, or alternatively, it may be detected that a voltage level of an output of a voltage regulator (e.g., such as the low-dropout voltage regulator 350-a of FIG. 3A) coupled with the supply rail is less than or equal to a second threshold voltage (e.g., that is a threshold amount less than a normal output voltage of the voltage regulator).

At 417, a discharge-stop command may be sent from the memory system to the host system. The discharge-stop command may direct the host system to refrain from activating a discharge component (e.g., such as the discharge component 220 of FIG. 2) configured to increase a rate of discharge for a disabled power management component (e.g., the power management component 215 of FIG. 2) that supplies power to the memory system, and thus to increase a rate of discharge for the conductive path between the power management component and the components of the memory system. Preventing this discharge operation may enable the voltage of the conductive path to remain above a threshold voltage for a longer duration relative to if the discharge operation were performed.

At 420, a switch (e.g., such as the switch in the switching component 355-a of FIG. 3A) may be activated to bypass the voltage regulator. In some examples, the switch is activated based on the level detection component detecting that the voltage level of the supply rail is less than or equal to the first threshold voltage. Additionally, or alternatively, the switch may be activated based on receiving a trigger associated with the low-power data retention command being broadcasted throughout the system.

FIG. 4B may illustrate voltage behavior in the case where the switch is not activated until the voltage level of the supply rail is less than or equal to the first threshold voltage. FIG. 4C may illustrate voltage behavior in the case where the switch is activated in response to the low-power data retention command being broadcasted.

Thus, the resistance (and thus energy consumption) introduced (or that would have otherwise been introduced) into the power system by the voltage regulator while the memory system is in the low-power data retention mode may be removed from the power system.

At 425, it may be detected whether the voltage level of the supply rail is less than or equal to a second threshold voltage (e.g., which may be which may equivalent to Vlo depicted in FIGS. 4B and 4C). If the voltage level of the supply rail is less than or equal to the second threshold voltage, the operations described with reference to 430 through 440 may be performed prior to performing the operations described with reference to 450. Otherwise, the operations described with reference to 445 may be performed prior to performing the operations described with reference to 450.

At 430, after detecting the voltage level of the supply rail is less than the second threshold voltage, a low-supply voltage flag may be set within the memory system. The low-supply voltage flag may indicate that the data stored in an SRAM is no longer considered reliable.

At 435, it may be detected that the voltage level of the supply rail is greater than or equal to a third threshold voltage—e.g., as a result of the device or host system returning to an active state and power being restored to the memory system.

At 440, the memory system may exit the low-power data retention mode—e.g., and return to a higher-power mode, such as a standby mode or an active mode. As part of exiting the low-power data mode, the memory system may perform a startup procedure associated with calibrating the memory system and applying settings for the memory system based on the low-supply voltage flag being set. The memory system may additionally reenable and remove the power-gating from the components of the memory system.

At 445, it may be detected that the voltage level of the supply rail is greater than or equal to the third threshold voltage, as similarly described with reference to 435. Accordingly, the memory system may exit the low-power data retention mode, and the low-supply voltage flag may not be set. Since the low-supply voltage flag has not been set, the memory system may skip the startup procedure upon exit from the low-power data retention mode.

At 450, the switch bypassing the voltage regulator for the SRAM may be deactivated as part of the memory system exiting the low-power data retention mode. Accordingly, the voltage regulator may be reincorporated into the power system for subsequent operation.

At 455, normal, non-low-power data retention operation may be resumed by the memory system.

Aspects of the flowchart 400-a may be implemented by a controller, among other components. Additionally, or alternatively, aspects of the flowchart 400-a may be implemented as instructions stored in memory (e.g., firmware stored in a memory coupled with a controller). For example, the instructions, when executed by a controller, may cause the controller to perform the operations of the flowchart 400-a.

One or more of the operations described in the flowchart 400-a may be performed earlier or later, omitted, replaced, supplemented, or combined with another operation. Also, additional operations described herein may replace, supplement or be combined with one or more of the operations described in the flowchart 400-a.

FIG. 4B shows example graphs for retaining data during low-power events in accordance with examples as disclosed herein.

The graph 400-b depicts a first duration during which power is supplied to a memory system (at a supply voltage, Vcc); a first time, t1, at which power is removed from the memory system; a second time, t2, at which the voltage of a supply rail within the memory system is less than or equal to a first threshold voltage, Vth; and a third time, t3, at which the voltage of the supply rail is less than or equal to a second threshold voltage, Vlo.

The supply voltage may be around 2.25V. The first threshold voltage, Vth, may be associated with (e.g., equivalent to or near) a voltage output by a low-dropout voltage regulator (e.g., the low-dropout voltage regulator 350-a of FIG. 3A). In some examples, the first threshold volage, Vth, is around 1.8 V. The second threshold voltage, Vlo, may be associated with (e.g., equivalent to or near) a data retention voltage at which an SRAM is capable of retaining data. In some examples, the first threshold volage, Vth, is between 0.8V and 1.2V.

When (at the second time, t2) the voltage of the supply rail is less than or equal to the first threshold voltage, Vth, a switching component (e.g., the switching component 355-a of FIG. 3A) may be enabled to bypass the low-dropout voltage regulator—e.g., to allow the voltage of the supply rail to continue to discharge around its current rate instead of having the un-bypassed low-dropout voltage regulator consume energy, accelerating the rate of decrease. In some examples, the switching component is enabled in response to a level detection component (e.g., the level detection component 235 of FIG. 2), detecting that the voltage of the supply rail is less than or equal to the threshold voltage.

If (at the third time, t3) the voltage of the supply rail continues to discharge below the second threshold voltage, Vlo—e.g., if power is not restored to the memory system prior to time, t3—a low-supply voltage flag may be set within the memory system. Thus, the memory system may perform a startup procedure when power is restored to the memory system. Otherwise, if the voltage of the supply rail is above the second threshold voltage, Vlo, when power is restored to the memory system, the low-voltage may not be set, and the memory system may resume operation without performing the startup procedure—e.g., as the core configurations of the memory system may be retained in the SRAM.

FIG. 4C shows example graphs for retaining data during low-power events in accordance with examples as disclosed herein.

The graph 400-c depicts a first duration during which power is supplied to a memory system (at a supply voltage, Vcc); a first time, t1, at which power is removed from the memory system; and a second time, t3, at which the voltage of the supply rail is less than or equal to a second threshold voltage, Vlo. The level of the voltages depicted in FIG. 4C may be similar to those described in FIG. 4B.

When (at the first time, t1) power is removed from the memory system, the switching component (e.g., the switching component 355-a of FIG. 3A) may be enabled to bypass the low-dropout voltage regulator—e.g., in response to the memory system receiving and/or issuing a command to enter a low-power data retention state.

If (at the second time, t2) the voltage of the supply rail continues to discharge below the second threshold voltage, Vlo, the low-supply voltage flag may be set within the memory system.

FIG. 5A shows an example of a set of operations for retaining data during low-power events in accordance with examples as disclosed herein.

The flowchart 500-a may be performed by a memory system, such as a memory system described herein. In some examples, the flowchart 500-a shows an example set of operations performed to support retaining data during low-power events. For example, the flowchart 500-a may include operations for changing an output voltage of a voltage regulator when power is removed from the memory system.

At 505, a low-power event command may be received, as similarly described with reference to the operations referenced at 405 of FIG. 4A.

At 510, a low-power data retention command may be broadcast throughout the memory system, as similarly described with reference to the operations referenced at 410 of FIG. 4A.

At 515, it may be detected that a voltage level of a supply rail or an output of a voltage regulator (e.g., such as the low-dropout voltage regulator 350-b of FIG. 3B) within the memory system is less than or equal to a respective threshold voltage, as similarly described with reference to the operations referenced at 415 of FIG. 4A.

At 517, a discharge-stop command may be sent from the memory system to the host system, as similarly described with reference to the operations referenced at 417 of FIG. 4A.

At 520, an output voltage of the voltage regulator may change from a first voltage level (e.g., around 1.8V) to a second voltage level (e.g., around 1.2V). In some examples, the output voltage of the voltage regulator is changed based on the level detection component detecting that the voltage level of the supply rail is less than or equal to the first threshold voltage. Additionally, or alternatively, the output voltage of the voltage regulator may be changed based on receiving a trigger associated with the low-power data retention command being broadcasted throughout the system.

FIG. 5B may illustrate voltage behavior in the case where the output voltage of the voltage regulator is not changed until the voltage level of the supply rail is less than or equal to the first threshold voltage. FIG. 5C may illustrate voltage behavior in the case where the output voltage of the voltage regulator is changed in response to the low-power data retention command being broadcasted.

Thus, the voltage regulator may continue to efficiently provide power at the lower voltage while the memory system is in the low-power data retention mode—e.g., until the supply voltage is less than or equal to the lowered output voltage of the voltage regulator.

At 525, it may be detected whether the voltage level of the supply rail is less than or equal to a second threshold voltage, as similarly described with reference to the operations referenced at 425 of FIG. 4A.

At 530, a low-supply voltage flag may be set within the memory system, as similarly described with reference to the operations referenced at 430 of FIG. 4A.

At 535, it may be detected that the voltage level of the supply rail is greater than or equal to a third threshold voltage, as similarly described with reference to the operations referenced at 435 of FIG. 4A.

At 540, the memory system may exit the low-power data retention mode, as similarly described with reference to the operations referenced at 440 of FIG. 4A.

At 545, it may be detected that the voltage level of the supply rail is greater than or equal to the third threshold voltage, as similarly described with reference to the operations referenced at 445 of FIG. 4A.

At 550, the voltage output of the voltage regulator may be restored to the higher voltage level as part of existing the low-power data retention mode. Accordingly, the voltage regulator may resume efficiently providing power at the higher voltage level.

At 555, normal, non-low-power data retention operation may be resumed by the memory system, as similarly described with reference to the operations referenced at 455 of FIG. 4A.

Aspects of the flowchart 500-a may be implemented by a controller, among other components. Additionally, or alternatively, aspects of the flowchart 500-a may be implemented as instructions stored in memory (e.g., firmware stored in a memory coupled with a controller). For example, the instructions, when executed by a controller, may cause the controller to perform the operations of the flowchart 500-a.

One or more of the operations described in the flowchart 500-a may be performed earlier or later, omitted, replaced, supplemented, or combined with another operation. Also, additional operations described herein may replace, supplement or be combined with one or more of the operations described in the flowchart 500-a.

FIG. 5B shows example graphs for retaining data during low-power events in accordance with examples as disclosed herein.

The graph 500-b depicts a first duration during which power is supplied to a memory system (at a supply voltage, Vcc); a first time, t1, at which power is removed from the memory system; a second time, t2, at which the voltage of a supply rail within the memory system is less than or equal to a first threshold voltage, Vth; and a third time, t3, at which the voltage of the supply rail is less than or equal to a second threshold voltage, Vlo. The level of the voltages depicted in FIG. 5B may be similar to those described in FIG. 4B.

When (at the second time, t2) the voltage of the supply rail is less than or equal to the first threshold voltage, Vth, an output voltage of a low-dropout voltage regulator (e.g., the low-dropout voltage regulator 350-b of FIG. 3B) may be reconfigured to output a lower voltage level—e.g., to allow the voltage of the supply rail to continue to discharge around its current rate instead of having the originally configured low-dropout voltage regulator consume energy, accelerating the rate of decrease. In some examples, the output voltage change is enabled in response to a level detection component (e.g., the level detection component 235 of FIG. 2), detecting that the voltage of the supply rail is less than or equal to the threshold voltage.

If (at the third time, t3) the voltage of the supply rail continues to discharge below the second threshold voltage, Vlo—e.g., if power is not restored to the memory system prior to time, t3—a low-supply voltage flag may be set within the memory system.

FIG. 5C shows example graphs for retaining data during low-power events in accordance with examples as disclosed herein.

The graph 500-c depicts a first duration during which power is supplied to a memory system (at a supply voltage, Vcc); a first time, t1, at which power is removed from the memory system; and a second time, t3, at which the voltage of the supply rail is less than or equal to a second threshold voltage, Vlo. The level of the voltages depicted in FIG. 5C may be similar to those described in FIG. 4B.

When (at the first time, t1) power is removed from the memory system, the low-dropout voltage regulator (e.g., the low-dropout voltage regulator 350-b of FIG. 3B) may be reconfigured to output a lower voltage level—e.g., in response to the memory system receiving and/or issuing a command to enter a low-power data retention state.

If (at the second time, t2) the voltage of the supply rail continues to discharge below the second threshold voltage, Vlo, the low-supply voltage flag may be set within the memory system.

FIG. 6A shows an example of a set of operations for retaining data during low-power events in accordance with examples as disclosed herein.

The flowchart 600-a may be performed by a memory system, such as a memory system described herein. In some examples, the flowchart 600-a shows an example set of operations performed to support retaining data during low-power events. For example, the flowchart 600-a may include operations for changing an output voltage of a voltage regulator when power is removed from the memory system.

At 605, a low-power event command may be received, as similarly described with reference to the operations referenced at 405 of FIG. 4A.

At 610, a low-power data retention command may be broadcast throughout the memory system, as similarly described with reference to the operations referenced at 410 of FIG. 4A.

At 615, it may be detected that a voltage level of a supply rail or an output of a voltage regulator (e.g., such as the low-dropout voltage regulator 350-c-1 of FIG. 3C) that generates a first voltage level (e.g., around 1.8V) within the memory system is less than or equal to a respective threshold voltage, as similarly described with reference to the operations referenced at 415 of FIG. 4A.

At 617, a discharge-stop command may be sent from the memory system to the host system, as similarly described with reference to the operations referenced at 417 of FIG. 4A.

At 620, the first voltage regulator may be disabled and a second voltage regulator (e.g., the low-dropout voltage regulator 350-c-2 of FIG. 3C) that generates a second voltage level (e.g., around 1.2V) may be enabled. In some examples, the first voltage regulator is disabled and the second voltage regulator is enabled based on the level detection component detecting that the voltage level of the supply rail is less than or equal to the first threshold voltage. Additionally, or alternatively, the first voltage regulator may be disabled and the second voltage regulator may be enabled based on receiving a trigger associated with the low-power data retention command being broadcasted throughout the system. In some examples, disabling the first voltage regulator may involve zeroing a reference voltage, which may cause an input resistance of the first voltage regulator to significantly increase, such that the current path is effectively diverted to the second voltage regulator.

FIG. 6B may illustrate voltage behavior in the case where the first voltage regulator is not disabled and the voltage regulator is not enabled until the voltage level of the supply rail is less than or equal to the first threshold voltage. FIG. 5C may illustrate voltage behavior in the case where the first voltage regulator is disabled and the voltage regulator is enabled in response to the low-power data retention command being broadcasted.

Thus, the second voltage regulator may continue to efficiently provide power at the lower voltage while the memory system is in the low-power data retention mode—e.g., until the supply voltage is less than or equal to the lowered output voltage of the second voltage regulator. Additionally, the resistance (and thus energy consumption) introduced (or that would have otherwise been introduced) into the power system by the first voltage regulator while the memory system is in the low-power data retention mode may be removed from the power system.

At 625, it may be detected whether the voltage level of the supply rail is less than or equal to a second threshold voltage, as similarly described with reference to the operations referenced at 425 of FIG. 4A.

At 630, a low-supply voltage flag may be set within the memory system, as similarly described with reference to the operations referenced at 430 of FIG. 4A.

At 635, it may be detected that the voltage level of the supply rail is greater than or equal to a third threshold voltage, as similarly described with reference to the operations referenced at 435 of FIG. 4A.

At 640, the memory system may exit the low-power data retention mode, as similarly described with reference to the operations referenced at 440 of FIG. 4A.

At 645, it may be detected that the voltage level of the supply rail is greater than or equal to the third threshold voltage, as similarly described with reference to the operations referenced at 445 of FIG. 4A.

At 650, the first voltage regulator may be enabled and the second voltage may be disabled. Accordingly, the first voltage regulator may resume efficiently providing power at the higher voltage level.

At 655, normal, non-low-power data retention operation may be resumed by the memory system, as similarly described with reference to the operations referenced at 455 of FIG. 4A.

Aspects of the flowchart 600-a may be implemented by a controller, among other components. Additionally, or alternatively, aspects of the flowchart 600-a may be implemented as instructions stored in memory (e.g., firmware stored in a memory coupled with a controller). For example, the instructions, when executed by a controller, may cause the controller to perform the operations of the flowchart 600-a.

One or more of the operations described in the flowchart 600-a may be performed earlier or later, omitted, replaced, supplemented, or combined with another operation. Also, additional operations described herein may replace, supplement or be combined with one or more of the operations described in the flowchart 600-a.

FIG. 6B shows example graphs for retaining data during low-power events in accordance with examples as disclosed herein.

The graph 600-b depicts a first duration during which power is supplied to a memory system (at a supply voltage, Vcc); a first time, t1, at which power is removed from the memory system; a second time, t2, at which the voltage of a supply rail within the memory system is less than or equal to a first threshold voltage, Vth; and a third time, t3, at which the voltage of the supply rail is less than or equal to a second threshold voltage, Vlo. The level of the voltages depicted in FIG. 6B may be similar to those described in FIG. 4B.

When (at the second time, t2) the voltage of the supply rail is less than or equal to the first threshold voltage, Vth, a first low-dropout voltage regulator (e.g., the first low-dropout voltage regulator 350-c-1 of FIG. 3C) that generates a first voltage (e.g., around 1.8V) may be disabled and a second low-dropout voltage regulator 350-c-2 of FIG. 3C) that generates a second voltage (e.g., around 1.2V) may be enabled—e.g., to allow the voltage of the supply rail to continue to discharge around its current rate instead of having the first low-dropout voltage regulator consume energy, accelerating the rate of decrease. In some examples, the low-dropout voltage regulator are enabled/disabled in response to a level detection component (e.g., the level detection component 235 of FIG. 2), detecting that the voltage of the supply rail is less than or equal to the threshold voltage.

If (at the third time, t3) the voltage of the supply rail continues to discharge below the second threshold voltage, Vlo—e.g., if power is not restored to the memory system prior to time, t3—a low-supply voltage flag may be set within the memory system.

FIG. 6C shows example graphs for retaining data during low-power events in accordance with examples as disclosed herein.

The graph 600-c depicts a first duration during which power is supplied to a memory system (at a supply voltage, Vcc); a first time, t1, at which power is removed from the memory system; and a second time, t3, at which the voltage of the supply rail is less than or equal to a second threshold voltage, Vlo. The level of the voltages depicted in FIG. 6C may be similar to those described in FIG. 4B.

When (at the first time, t1) power is removed from the memory system, the first low-dropout voltage regulator (e.g., the first low-dropout voltage regulator 350-c-1 of FIG. 3C) that generates a first voltage (e.g., around 1.8V) may be disabled and the second low-dropout voltage regulator 350-c-2 of FIG. 3C) that generates a second voltage (e.g., around 1.2V) may be enabled—e.g., in response to the memory system receiving and/or issuing a command to enter a low-power data retention state.

If (at the second time, t2) the voltage of the supply rail continues to discharge below the second threshold voltage, Vlo, the low-supply voltage flag may be set within the memory system.

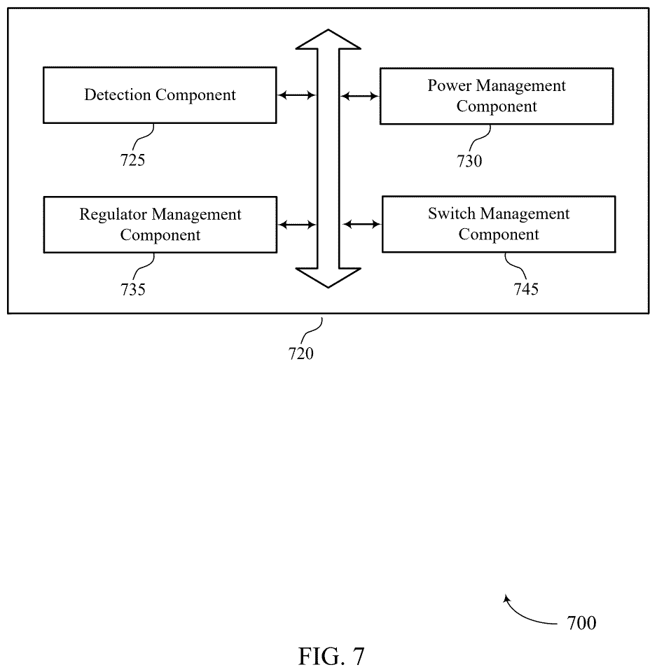

FIG. 7 shows a block diagram 700 of a memory system 720 that supports retaining data during low-power events in accordance with examples as disclosed herein. The memory system 720 may be an example of aspects of a memory system as described with reference to FIGS. 1 through 6. The memory system 720, or various components thereof, may be an example of means for performing various aspects of retaining data during low-power events as described herein. For example, the memory system 720 may include a detection component 725, a power management component 730, a regulator management component 735, a switch management component 745, or any combination thereof. Each of these components, or components of subcomponents thereof (e.g., one or more processors, one or more memories), may communicate, directly or indirectly, with one another (e.g., via one or more buses).

The detection component 725 may be configured as or otherwise support a means for receiving an indication that a low-power mode associated with the memory system has been activated, where a voltage supplied to the memory system is altered as a result of the low-power mode being activated. The power management component 730 may be configured as or otherwise support a means for performing, in accordance with receiving the indication, one or more operations to extend a duration after the voltage is altered during which a voltage applied to the volatile memory device remains above a threshold voltage associated with retaining data stored in the volatile memory device.

In some examples, performing the one or more operations includes activating a switch that bypasses a voltage regulator positioned between a supply rail of the memory system and a supply rail of the volatile memory device.

In some examples, the detection component 725 may be configured as or otherwise support a means for detecting that a voltage of the supply rail of the memory system is less than or equal to a second threshold voltage and greater than the threshold voltage, where the switch is activated in accordance with the detecting.

In some examples, the detection component 725 may be configured as or otherwise support a means for detecting, after activating the switch, that a voltage of the supply rail of the memory system is greater than or equal to a third threshold voltage, the third threshold voltage being greater than the second threshold voltage. In some examples, the switch management component 745 may be configured as or otherwise support a means for deactivating the switch in accordance with the detecting.

In some examples, performing the one or more operations includes changing an output of a voltage regulator positioned between a supply rail of the memory system and a supply rail of the volatile memory device from a first output voltage to a second output voltage that is less than the first output voltage and greater than or equal to the threshold voltage.

In some examples, the output of the voltage regulator is changed from the first output voltage to the second output voltage in response to receiving the indication.

In some examples, the detection component 725 may be configured as or otherwise support a means for detecting, after changing the output of the voltage regulator, that a voltage of the supply rail of the memory system is greater than or equal to a second threshold voltage. In some examples, the regulator management component 735 may be configured as or otherwise support a means for returning the output of the voltage regulator to the first output voltage in accordance with the detecting.

In some examples, the detection component 725 may be configured as or otherwise support a means for receiving, after changing the output of the voltage regulator, an indication that at least a portion of the memory system has exited a low-power state. In some examples, the regulator management component 735 may be configured as or otherwise support a means for returning the output of the voltage regulator to the first output voltage in accordance with the portion of the memory system exiting the low-power state.

In some examples, performing the one or more operations includes disabling a first voltage regulator positioned between a supply rail of the memory system and a supply rail of the volatile memory device; and enabling a second voltage regulator positioned between the supply rail of the memory system and the supply rail of the volatile memory device. In some examples, the first voltage regulator is configured to output a first voltage. In some examples, the second voltage regulator is configured to output a second voltage that is less than the first voltage and greater than or equal to the threshold voltage.

In some examples, the first voltage regulator is disabled and the second voltage regulator is enabled in response to receiving the indication.

In some examples, the detection component 725 may be configured as or otherwise support a means for detecting, after disabling the first voltage regulator and enabling the second voltage regulator, that a voltage of the supply rail of the memory system is greater than or equal to a second threshold voltage. In some examples, the regulator management component 735 may be configured as or otherwise support a means for enabling the first voltage regulator in accordance with the detecting. In some examples, the regulator management component 735 may be configured as or otherwise support a means for disabling the second voltage regulator in accordance with the detecting.

In some examples, the detection component 725 may be configured as or otherwise support a means for detecting, after disabling the first voltage regulator and enabling the second voltage regulator, that a voltage of the supply rail of the memory system is greater than or equal to a second threshold voltage. In some examples, the regulator management component 735 may be configured as or otherwise support a means for enabling the first voltage regulator in accordance with the detecting. In some examples, the regulator management component 735 may be configured as or otherwise support a means for disabling the second voltage regulator in accordance with the detecting.

In some examples, the detection component 725 may be configured as or otherwise support a means for receiving, after disabling the first voltage regulator and enabling the second voltage regulator, an indication that a second component of the memory system has exited a low-power state. In some examples, the regulator management component 735 may be configured as or otherwise support a means for enabling the first voltage regulator in accordance with the second component of the memory system exiting the low-power state. In some examples, the regulator management component 735 may be configured as or otherwise support a means for disabling the second voltage regulator in accordance with the second component of the memory system exiting the low-power state.

In some examples, performing the one or more operations includes entering a low-power mode associated with retaining data stored in the volatile memory device.

In some examples, entering the low-power mode includes disabling first components of the memory system that are independent of the volatile memory device, disconnecting second components of the memory system from power, or both.

In some examples, a first portion of the volatile memory device stores configuration information for the memory system. In some examples, entering the low-power mode includes disabling a second portion of the volatile memory device.

In some examples, the power management component 730 may be configured as or otherwise support a means for transmitting a response to the indication directing a host system to disable a component configured to discharge a circuit at the host system that provides power to the memory system before the host system enters the low-power mode.

In some examples, the described functionality of the memory system 720, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 720, or various components thereof, may be implemented at least in part by instructions (e.g., stored in memory, non-transitory computer-readable medium) executable by such at least one processor.

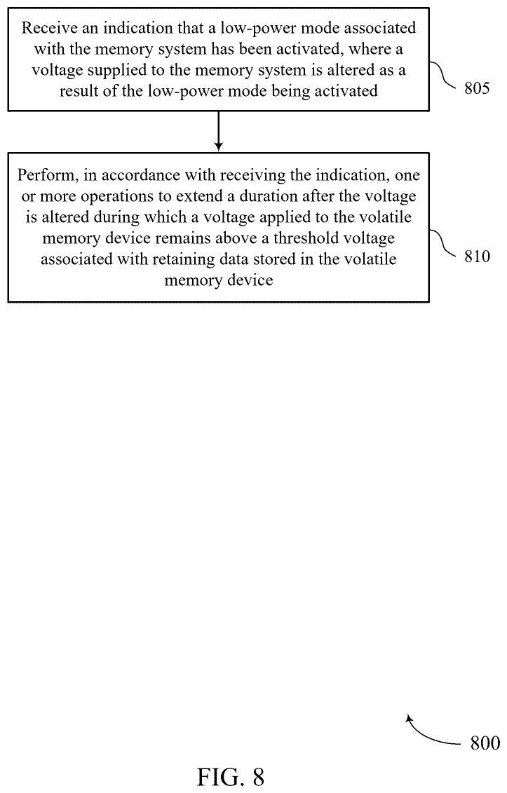

FIG. 8 shows a flowchart illustrating a method 800 that supports retaining data during low-power events in accordance with examples as disclosed herein. The operations of method 800 may be implemented by a memory system or its components as described herein. For example, the operations of method 800 may be performed by a memory system as described with reference to FIGS. 1 through 7. In some examples, a memory system may execute a set of instructions to control the functional elements of the device to perform the described functions. Additionally, or alternatively, the memory system may perform aspects of the described functions using special-purpose hardware.

At 805, the method may include receiving an indication that a low-power mode associated with the memory system has been activated, where a voltage supplied to the memory system is altered as a result of the low-power mode being activated. In some examples, aspects of the operations of 805 may be performed by a detection component 725 as described with reference to FIG. 7.

At 810, the method may include performing, in accordance with receiving the indication, one or more operations to extend a duration after the voltage is altered during which a voltage applied to the volatile memory device remains above a threshold voltage associated with retaining data stored in the volatile memory device. In some examples, aspects of the operations of 810 may be performed by a power management component 730 as described with reference to FIG. 7.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving an indication that a low-power mode associated with the memory system has been activated, where a voltage supplied to the memory system is altered as a result of the low-power mode being activated and performing, in accordance with receiving the indication, one or more operations to extend a duration after the voltage is altered during which a voltage applied to the volatile memory device remains above a threshold voltage associated with retaining data stored in the volatile memory device.

Aspect 2: The method, apparatus, or non-transitory computer-readable medium of aspect 1, where performing the one or more operations includes activating a switch that bypasses a voltage regulator positioned between a supply rail of the memory system and a supply rail of the volatile memory device.

Aspect 3: The method, apparatus, or non-transitory computer-readable medium of aspect 2, further including operations, features, circuitry, logic, means, or instructions, or any combination thereof for detecting that a voltage of the supply rail of the memory system is less than or equal to a second threshold voltage and greater than the threshold voltage, where the switch is activated in accordance with the detecting.

Aspect 4: The method, apparatus, or non-transitory computer-readable medium of aspect 3, further including operations, features, circuitry, logic, means, or instructions, or any combination thereof for detecting, after activating the switch, that a voltage of the supply rail of the memory system is greater than or equal to a third threshold voltage, the third threshold voltage being greater than the second threshold voltage and deactivating the switch in accordance with the detecting.

Aspect 5: The method, apparatus, or non-transitory computer-readable medium of any of aspects 1 through 4, where performing the one or more operations includes changing an output of a voltage regulator positioned between a supply rail of the memory system and a supply rail of the volatile memory device from a first output voltage to a second output voltage that is less than the first output voltage and greater than or equal to the threshold voltage.

Aspect 6: The method, apparatus, or non-transitory computer-readable medium of aspect 5, where the output of the voltage regulator is changed from the first output voltage to the second output voltage in response to receiving the indication.

Aspect 7: The method, apparatus, or non-transitory computer-readable medium of any of aspects 5 through 6, further including operations, features, circuitry, logic, means, or instructions, or any combination thereof for detecting, after changing the output of the voltage regulator, that a voltage of the supply rail of the memory system is greater than or equal to a second threshold voltage and returning the output of the voltage regulator to the first output voltage in accordance with the detecting.

Aspect 8: The method, apparatus, or non-transitory computer-readable medium of any of aspects 5 through 7, further including operations, features, circuitry, logic, means, or instructions, or any combination thereof for receiving, after changing the output of the voltage regulator, an indication that at least a portion of the memory system has exited a low-power state and returning the output of the voltage regulator to the first output voltage in accordance with the portion of the memory system exiting the low-power state.

Aspect 9: The method, apparatus, or non-transitory computer-readable medium of any of aspects 1 through 8, where performing the one or more operations includes disabling a first voltage regulator positioned between a supply rail of the memory system and a supply rail of the volatile memory device; and enabling a second voltage regulator positioned between the supply rail of the memory system and the supply rail of the volatile memory device; the first voltage regulator is configured to output a first voltage; and the second voltage regulator is configured to output a second voltage that is less than the first voltage and greater than or equal to the threshold voltage.

Aspect 10: The method, apparatus, or non-transitory computer-readable medium of aspect 9, where the first voltage regulator is disabled and the second voltage regulator is enabled in response to receiving the indication.

Aspect 11: The method, apparatus, or non-transitory computer-readable medium of any of aspects 9 through 10, further including operations, features, circuitry, logic, means, or instructions, or any combination thereof for detecting, after disabling the first voltage regulator and enabling the second voltage regulator, that a voltage of the supply rail of the memory system is greater than or equal to a second threshold voltage; enabling the first voltage regulator in accordance with the detecting; and disabling the second voltage regulator in accordance with the detecting.

Aspect 12: The method, apparatus, or non-transitory computer-readable medium of any of aspects 9 through 11, further including operations, features, circuitry, logic, means, or instructions, or any combination thereof for detecting, after disabling the first voltage regulator and enabling the second voltage regulator, that a voltage of the supply rail of the memory system is greater than or equal to a second threshold voltage; enabling the first voltage regulator in accordance with the detecting; and disabling the second voltage regulator in accordance with the detecting.

Aspect 13: The method, apparatus, or non-transitory computer-readable medium of any of aspects 9 through 12, further including operations, features, circuitry, logic, means, or instructions, or any combination thereof for receiving, after disabling the first voltage regulator and enabling the second voltage regulator, an indication that a second component of the memory system has exited a low-power state; enabling the first voltage regulator in accordance with the second component of the memory system exiting the low-power state; and disabling the second voltage regulator in accordance with the second component of the memory system exiting the low-power state.

Aspect 14: The method, apparatus, or non-transitory computer-readable medium of any of aspects 1 through 13, where performing the one or more operations includes entering a low-power mode associated with retaining data stored in the volatile memory device.

Aspect 15: The method, apparatus, or non-transitory computer-readable medium of aspect 14, where entering the low-power mode includes disabling first components of the memory system that are independent of the volatile memory device, disconnecting second components of the memory system from power, or both.

Aspect 16: The method, apparatus, or non-transitory computer-readable medium of any of aspects 14 through 15, where a first portion of the volatile memory device stores configuration information for the memory system and entering the low-power mode includes disabling a second portion of the volatile memory device.

Aspect 17: The method, apparatus, or non-transitory computer-readable medium of any of aspects 1 through 16, further including operations, features, circuitry, logic, means, or instructions, or any combination thereof for transmitting a response to the indication directing a host system to disable a component configured to discharge a circuit at the host system that provides power to the memory system before the host system enters the low-power mode.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

As used herein, the term “substantially” means that the modified characteristic (e.g., a verb or adjective modified by the term substantially) need not be absolute but is close enough to achieve the advantages of the characteristic.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more non-volatile memory devices;
a volatile memory device; and
processing circuitry coupled with the one or more non-volatile memory devices and the volatile memory device, the processing circuitry configured to cause the memory system to:
receive an indication that a low-power mode associated with the memory system has been activated, wherein a voltage supplied to the memory system is altered as a result of the low-power mode being activated; and
perform, in accordance with receiving the indication, one or more operations to extend a duration after the voltage is altered during which a voltage applied to the volatile memory device remains above a threshold voltage associated with retaining data stored in the volatile memory device.

2. The memory system of claim 1, wherein the processing circuitry configured to cause the memory system to perform the one or more operations is further configured to cause the memory system to:
activate a switch that bypasses a voltage regulator positioned between a supply rail of the memory system and a supply rail of the volatile memory device.

3. The memory system of claim 2, wherein the processing circuitry is further configured to cause the memory system to:
detect that a voltage of the supply rail of the memory system is less than or equal to a second threshold voltage and greater than the threshold voltage, wherein the switch is activated in accordance with the detecting.

4. The memory system of claim 3, wherein the processing circuitry is further configured to cause the memory system to:
detect, after activating the switch, that a voltage of the supply rail of the memory system is greater than or equal to a third threshold voltage, the third threshold voltage being greater than the second threshold voltage; and
deactivate the switch in accordance with the detecting.

5. The memory system of claim 1, wherein the processing circuitry configured to cause the memory system to perform the one or more operations is further configured to cause the memory system to:
change an output of a voltage regulator positioned between a supply rail of the memory system and a supply rail of the volatile memory device from a first output voltage to a second output voltage that is less than the first output voltage and greater than or equal to the threshold voltage.

6. The memory system of claim 5, wherein the output of the voltage regulator is changed from the first output voltage to the second output voltage in response to receiving the indication.

7. The memory system of claim 5, wherein the processing circuitry is further configured to cause the memory system to:
detect, after changing the output of the voltage regulator, that a voltage of the supply rail of the memory system is greater than or equal to a second threshold voltage; and
return the output of the voltage regulator to the first output voltage in accordance with the detecting.

8. The memory system of claim 5, wherein the processing circuitry is further configured to cause the memory system to:
receive, after changing the output of the voltage regulator, an indication that at least a portion of the memory system has exited a low-power state; and
return the output of the voltage regulator to the first output voltage in accordance with the portion of the memory system exiting the low-power state.

9. The memory system of claim 1, wherein the processing circuitry configured to cause the memory system to perform the one or more operations comprises is further configured to cause the memory system to:
disable a first voltage regulator positioned between a supply rail of the memory system and a supply rail of the volatile memory device; and
enable a second voltage regulator positioned between the supply rail of the memory system and the supply rail of the volatile memory device, wherein the first voltage regulator is configured to output a first voltage, and wherein the second voltage regulator is configured to output a second voltage that is less than the first voltage and greater than or equal to the threshold voltage.

10. The memory system of claim 9, wherein the first voltage regulator is disabled and the second voltage regulator is enabled in response to receiving the indication.

11. The memory system of claim 9, wherein the processing circuitry is further configured to cause the memory system to:
detect, after disabling the first voltage regulator and enabling the second voltage regulator, that a voltage of the supply rail of the memory system is greater than or equal to a second threshold voltage;
enable the first voltage regulator in accordance with the detecting; and
disable the second voltage regulator in accordance with the detecting.

12. The memory system of claim 9, wherein the processing circuitry is further configured to cause the memory system to:
detect, after disabling the first voltage regulator and enabling the second voltage regulator, that a voltage of the supply rail of the memory system is greater than or equal to a second threshold voltage;
enable the first voltage regulator in accordance with the detecting; and
disable the second voltage regulator in accordance with the detecting.

13. The memory system of claim 9, wherein the processing circuitry is further configured to cause the memory system to:
receive, after disabling the first voltage regulator and enabling the second voltage regulator, an indication that a second component of the memory system has exited a low-power state;
enable the first voltage regulator in accordance with the second component of the memory system exiting the low-power state; and
disable the second voltage regulator in accordance with the second component of the memory system exiting the low-power state.

14. The memory system of claim 1, wherein the processing circuitry configured to cause the memory system to perform the one or more operations is further configured to cause the memory system to:
enter a low-power mode associated with retaining data stored in the volatile memory device.

15. The memory system of claim 14, wherein the processing circuitry configured to cause the memory system to enter the low-power mode comprises is further configured to cause the memory system to:
disable first components of the memory system that are independent of the volatile memory device, disconnecting second components of the memory system from power, or both.

16. The memory system of claim 14, wherein:
a first portion of the volatile memory device stores configuration information for the memory system, and
the processing circuitry configured to cause the memory system to enter the low-power mode is further configured to cause the memory system to disable a second portion of the volatile memory device.

17. The memory system of claim 1, wherein the processing circuitry is further configured to cause the memory system to:
transmit a response to the indication directing a host system to disable a component configured to discharge a circuit at the host system that provides power to the memory system before the host system enters the low-power mode.

18. A non-transitory, computer-readable medium storing code comprising instructions executable by processing circuitry of a memory system to cause the memory system to:
receive an indication that a low-power mode has been activated, wherein a voltage supplied to the memory system is altered as a result of the low-power mode being activated; and
perform, in accordance with receiving the indication, one or more operations to extend a duration after the voltage is altered during which a voltage applied to a volatile memory device of the memory system remains above a threshold voltage associated with retaining data stored in the volatile memory device.

19. The non-transitory, computer-readable medium of claim 18, wherein the instructions executable to cause the memory system to perform the one or more operations are further executable by the processing circuitry to cause the memory system to:
activate a switch that bypasses a voltage regulator positioned between a supply rail of the memory system and a supply rail of the volatile memory device.

20. The non-transitory, computer-readable medium of claim 18, wherein the instructions executable to cause the memory system to perform the one or more operations are further executable by the processing circuitry to cause the memory system to:
change an output of a voltage regulator positioned between a supply rail of the memory system and a supply rail of the volatile memory device from a first output voltage to a second output voltage that is less than the first output voltage and greater than or equal to the threshold voltage.

21. The non-transitory, computer-readable medium of claim 18, wherein the instructions executable to cause the memory system to perform the one or more operations are further executable by the processing circuitry to cause the memory system to:
disable a first voltage regulator positioned between a supply rail of the memory system and a supply rail of the volatile memory device; and
enable a second voltage regulator positioned between the supply rail of the memory system and the supply rail of the volatile memory device, wherein the first voltage regulator is configured to output a first voltage, and wherein the second voltage regulator is configured to output a second voltage that is less than the first voltage and greater than or equal to the threshold voltage.

22. The non-transitory, computer-readable medium of claim 18, wherein the instructions executable to cause the memory system to perform the one or more operations are further executable by the processing circuitry to cause the memory system to:
enter a low-power mode associated with retaining data stored in the volatile memory device.

23. A method at a memory system, comprising:
receiving an indication that a low-power mode has been activated, wherein a voltage supplied to a memory system is altered as a result of the low-power mode being activated; and
performing, in accordance with receiving the indication, one or more operations to extend a duration after the voltage is altered during which a voltage applied to a volatile memory device of the memory system remains above a threshold voltage associated with retaining data stored in the volatile memory device.
